(19) United States
(12) Patent Application Publication
(10) Pub. No.: US 2016/0284535 A1
(43) Pub. Date: Sep. 29, 2016

(54) METHOD FOR WET STRIPPING SILICON-CONTAINING ORGANIC LAYERS

(71) Applicant: TEL FSI, Inc., Chaska, MN (US)

(72) Inventors: Jeffrey M. Lauerhaas, Waconia, MN (US); Anthony S. Ratkovich, Bloomington, MN (US); Erik R. Berg, Chaska, MN (US); Jeffery W. Butterbaugh, Eden Prairie, MN (US); Robert Thomas John Matz, Waconia, MN (US); David DeKraker, Burnsville, MN (US)

(21) Appl. No.: 14/671,897

(22) Filed: Mar. 27, 2015

(51) Int. Cl. H01L 21/02; G03F 7/42

(52) U.S. Cl. CPC H01L 21/02057; G03F 7/426; G03F 7/423

(57) ABSTRACT

A method for stripping material from a microelectronic workpiece is described. The method includes receiving a workpiece having a surface exposing a layer composed of silicon and organic material, and placing the workpiece in a wet clean chamber. In the wet clean chamber, the layer composed of silicon and organic material is removed from the workpiece by exposing the surface of the workpiece to a first stripping agent containing a sulfuric acid composition, and then optionally exposing the surface of the workpiece to a second stripping agent containing dilute hydrofluoric acid (dHF).

### FIELD OF INVENTION

The invention relates to a method for stripping a layer from a microelectronic workpiece, and particularly, a method for stripping a layer composed of silicon and organic material.

### BACKGROUND OF THE INVENTION

Photolithography is a mainstay technique used to manufacture semiconductor integrated circuitry by transferring geometric shapes and patterns on a mask to the surface of a semiconductor workpiece. In principle, a light sensitive material is exposed to patterned light to alter its solubility in a developing solution. Once imaged and developed, the portion of the light sensitive material that is soluble in the developing chemistry is removed, and the circuit pattern remains.

Once the circuit pattern is initially formed in the light sensitive material, the patterned layer serves as a protective film that masks some regions of the semiconductor workpiece, while other regions are exposed to permit transfer of the circuit pattern to an underlying layer utilizing a dry etching process, such as a plasma etch process. In order to produce smaller critical dimensions and thinner layers/features in the initial patterned layer, multi-layer schemes can be implemented, including bi-layer masks or tri-layer masks. With the inclusion of a second or third layer, the uppermost patterned layer may be thinner than the thickness customarily chosen to withstand the subsequent dry etching process(es).

In multi-layer masks, an organic or inorganic anti-reflective coating (ARC) layer may be formed underlying the layer of light sensitive material to reduce reflected light and lessen the formation a standing wave pattern in the layer of light sensitive material. Silicon-containing ARC (SiARC) layers are now in production as anti-reflective mask layers, wherein the Si-content may be tuned to provide high etch selectivity to the light sensitive material, e.g. photoresist. Typically, SiARC layers are removed using a plasma ashing process, followed by a wet strip to clean residue. However, plasma ashing processes can cause damage to the underlying microelectronic workpiece. And furthermore, with process sequences increasing in complexity, the removal of advanced SiARC layers has become more problematic, and thus, new processing methods for removing these materials and other layers are needed for microelectronic device production.

### SUMMARY OF THE INVENTION

Embodiments of the invention relate to a method for stripping a layer from a microelectronic workpiece, and particularly, to a method for stripping a layer composed of silicon and organic material.

According to one embodiment, a method for stripping material from a microelectronic workpiece is described. The method includes receiving a workpiece having a surface exposing a layer composed of silicon and organic material, and placing the workpiece in a wet clean chamber. In the wet clean chamber, the layer composed of silicon and organic material is removed from the workpiece by exposing the surface of the workpiece to a first stripping agent containing a sulfuric acid composition, and then optionally exposing the surface of the workpiece to a second stripping agent containing dilute hydrofluoric acid (dHF).

### BRIEF DESCRIPTION OF THE DRAWINGS

In the accompanying drawings:

FIGS. 1A and 1B illustrate a schematic representation of a microelectronic workpiece having a layer composed of silicon and organic material according to an embodiment;

FIGS. 2A and 2B illustrate a schematic representation of a microelectronic workpiece having a layer composed of silicon and organic material according to another embodiment;

FIGS. 3A and 3B illustrate a schematic representation of a microelectronic workpiece having a layer composed of silicon and organic material according to yet another embodiment;

FIG. 4 provides a flow chart illustrating a method for stripping material from a microelectronic workpiece according to an embodiment;

FIGS. 5A and 5B are an illustration of a wet clean chamber according to additional embodiments; and

FIG. 6 an illustration of a wet clean chamber according to yet additional embodiments.

### DETAILED DESCRIPTION OF SEVERAL EMBODIMENTS

Methods for stripping material from a microelectronic workpiece are described in various embodiments. One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

“Workpiece” as used herein generically refers to the object being processed in accordance with the invention. The workpiece may include any material portion or structure of a device, particularly a semiconductor or other electronics device, and may, for example, be a base workpiece structure, such as a semiconductor wafer or a layer on or overlying a base workpiece structure such as a thin film. The workpiece may be a conventional silicon workpiece or other bulk workpiece comprising a layer of semi-conductive material. As used herein, the term “bulk workpiece” means and includes not only silicon wafers, but also silicon-on-insulator (“SOI”) workpieces, such as silicon-on-sapphire (“SOS”) workpieces and silicon-on-glass (“SOG”) workpieces, epitaxial layers of silicon on a base semiconductor foundation, and other semiconductor or optoelectronic materials, such as silicon-germanium, germanium, gallium arsenide, gallium nitride, and indium phosphide. The workpiece may be doped or undoped. Thus, workpiece is not intended to be limited to any particular base structure, underlying layer or overlying layer, patterned or un-patterned, but rather, is contemplated to include any such layer or base structure, and any combination of layers and/or base structures. The description below may reference particular types of workpieces, but this is for illustrative purposes only and not limitation.

As previously noted, layers containing silicon and organic material are now in production, and serve, among other things, as anti-reflective coatings for lithography and patterning mask layers for pattern transfer using etch processes. As an example, silicon containing ARC layers include silicon and organic material, and are currently used in microelectronic device fabrication. As further noted above, the Si-content can be tuned to provide high etch selectivity to the light sensitive material, e.g., photoresist. Typically, layers containing silicon and organic material are removed using a plasma ashing process, followed by a wet strip to clean, among other things, post-ash residue. The dry, followed by wet process sequence requires at least two processing tools and long cycle time. Alternatively, an all wet process involving two or more chemistries in separate processing tools can be used. However, plasma ashing processes can cause damage to the underlying microelectronic workpiece, and with increasing silicon content in such films, their removal has become more problematic.

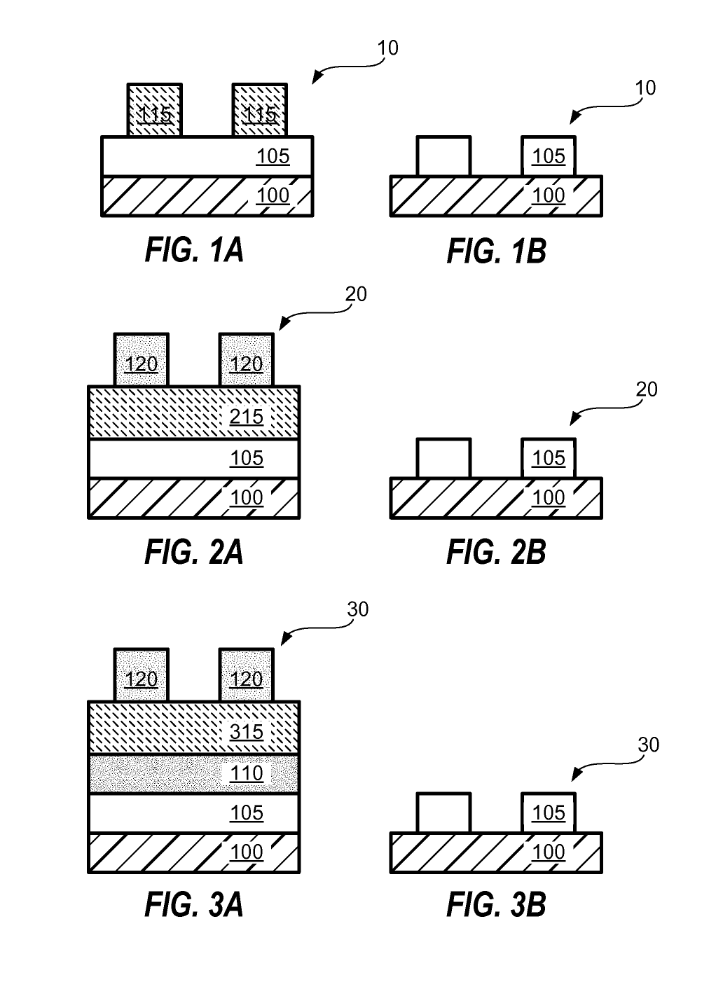

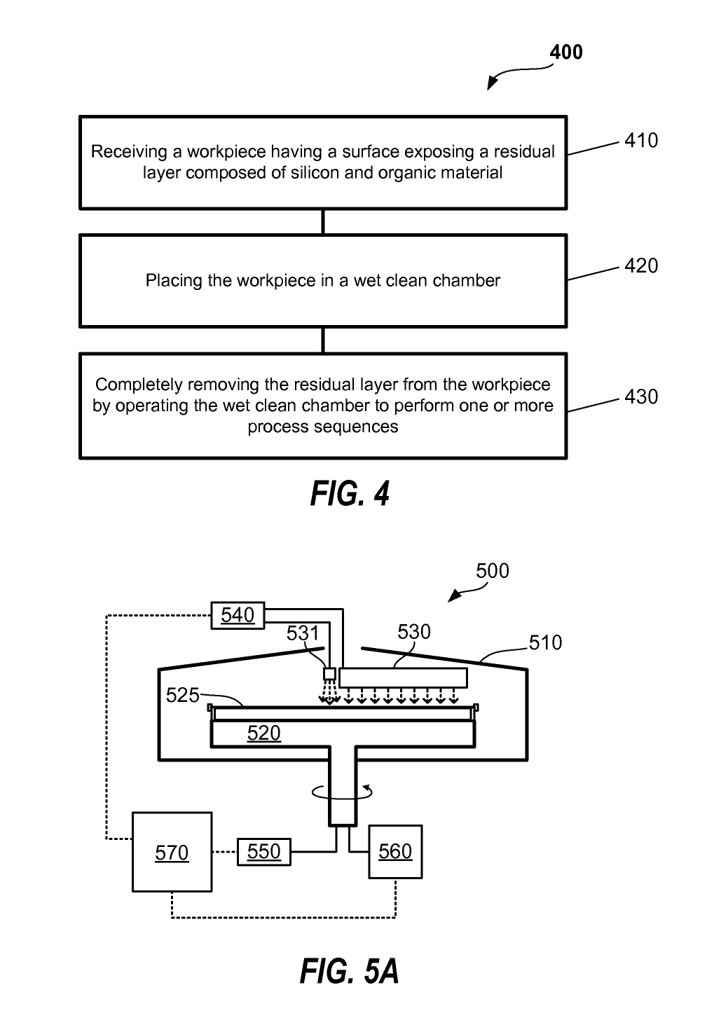

Referring now to the drawings, wherein like reference numerals designate identical or corresponding parts throughout the several views, FIGS. 1A, 1B, 2A, 2B, 3A, 3B, and 4 illustrate a method for stripping material from a microelectronic workpiece. The method is pictorially illustrated in FIGS. 1A, 2A, and 3A, and presented by way of a flow chart 400 in FIG. 4. As presented in FIG. 4, the flow chart 400 begins in 410 with receiving a workpiece 100 having a surface exposing a layer 115, 215, 315 composed of silicon and organic material.

As shown in FIG. 1A, the layer 115 can include, for example, a silicon containing ARC layer that may or may not possess a pattern to be transferred to an underlying layer (see FIG. 1B). Alternatively, as shown in FIG. 2A, the layer 215 can include, for example, a silicon containing ARC layer integrated within a multilayer film stack including remnants of an overlying photo-sensitive material 120 that may or may not possess a pattern to be transferred to an underlying layer (see FIG. 2B). Alternatively yet, as shown in FIG. 3A, the layer 315 can include, for example, a silicon containing ARC layer integrated within a multilayer film stack including remnants of an overlying photo-sensitive material 120 and an underlying organic layer 110 that may or may not possess a pattern to be transferred to an underlying layer (see FIG. 3B). As shown in FIGS. 1A, 2A, and 3A, according to some embodiments, the photo-sensitive material 120 and/or the organic layer 110 may be omitted and the layer 115 is deposited directly on the workpiece 100, or on a dielectric layer, a semiconductor layer, or a conductor layer.

Workpiece 100 further includes device layer 105. The device layer 105 can include any thin film or structure on workpiece 100 into which a pattern is to be transferred. Workpiece 100 can include a bulk silicon substrate, a single crystal silicon (doped or un-doped) substrate, a semiconductor-on-insulator (SOI) substrate, or any other semiconductor substrate containing, for example, Si, SiC, SiGe, SiGeC, Ge, GaAs, InAs, InP, as well as other III/V or II/VI compound semiconductors, or any combination thereof (Groups II, III, V, VI refer to the classical or old IUPAC notation in the Periodic Table of Elements; according to the revised or new IUPAC notation, these Groups would refer to Groups 2, 13, 15, 16, respectively). The workpiece can be of any size, for example, a 200 mm (millimeter) substrate, a 300 mm substrate, a 450 mm substrate, or an even larger substrate.

The layer 115, 215, 315 composed of silicon and organic material can be initially prepared by spin-coating the workpiece 100 with a thin film of material prior to applying materials for creating subsequent layers for lithography. Alternatively, layer 115, 215, 315 composed of silicon and organic material can be initially prepared using vapor deposition techniques, such as chemical vapor deposition (CVD), pyrolytic CVD, catalytic CVD, atomic layer deposition (ALD), etc. The silicon content in the layer 115, 215, 315 can be varied. For example, in some embodiments, the silicon content can be less than 40%, 30%, or 20%, or even 10%. And, in other embodiments, the silicon content can be greater than 40%. Exemplary silicon containing ARC layers, currently in production for photolithography, can have a silicon-content of 17% by weight Si (SiARC 17%), or a silicon-content of 43% by weight Si (SiARC 43%). For example, silicon containing ARC layers are commercially available from Shin Etsu Chemical Co., Ltd., among other chemical suppliers.

The organic layer 110 can include a photo-sensitive organic polymer or an etch type organic compound. For instance, the photo-sensitive organic polymer may be polyacrylate resin, epoxy resin, phenol resin, polyamide resin, polyimide resin, unsaturated polyester resin, polyphenylenether resin, polyphenylenesulfide resin, or benzocyclobutene (BCB). These materials may be formed using spin-on techniques. The organic layer 110 may be an organic material (e.g., (CHₓ)ₙ) that forms a cross-linked structure during a curing process.

In 420, the workpiece is placed in a wet clean chamber, to be described in greater detail below. And, in 430, the layer composed of silicon and organic material is completely removed from the workpiece 100 by operating the wet clean chamber to perform one or more process sequences (see FIGS. 1B, 2B, and 3B).

According to various embodiments, the one or more process sequences performed in the wet clean chamber can be used in semiconductor manufacturing, wherein the process sequences to be described enable a simplified process flow and reduce capital equipment requirements, among other things. Multi-level film stacks for etch and implant masks, as shown in FIGS. 2A and 3A, are used in multiple front end of the line (FEOL) processing steps. The multi-level film stack can be removed either after use, or in the event that the formation/patterning of the multi-layer film stack does not meet processing specifications, multi-level film stack can be removed and then deposited a second time (i.e., rework).

In one embodiment, the one or more process sequences include exposing the surface of the workpiece 100 to a first stripping agent containing a sulfuric acid composition. The exposing of the workpiece 100 can include dispensing the sulfuric acid composition onto the workpiece 100, or immersing the workpiece in a bath containing the sulfuric acid composition. The sulfuric acid composition can include a liquid-phase sulfuric acid composition containing sulfuric acid and/or its desiccating species and precursors. For example, the sulfuric acid composition can include sulfuric acid at a concentration of approximately 96 wt % to approximately 98 wt % (% by weight) sulfuric acid. Furthermore, the sulfuric acid composition can include a mixture containing sulfuric acid and at least one other ingredient. For example, the sulfuric acid composition can further include an oxidizing agent, such as a peroxide (i.e., hydrogen peroxide in a sulfuric acid-hydrogen peroxide mixture, or SPM), ozone or aqueous ozone. Additionally, for example, the hydrogen peroxide can include approximately 30 wt % to 32 wt % aqueous hydrogen peroxide solution.

The sulfuric acid may be heated to a temperature in excess of 70 degrees C., or 150 degrees C., or alternatively, to a temperature in excess of 200 degrees C. For example, the sulfuric acid is heated to a temperature ranging from approximately 70 degrees C. to approximately 220 degrees C. prior to mixing the sulfuric acid with additional material, such as hydrogen peroxide. Additionally, for example, the sulfuric acid is heated to a temperature ranging from approximately 170 degrees C. to approximately 200 degrees C. prior to mixing the sulfuric acid with additional material, such as hydrogen peroxide.

Furthermore, water, such as steam, may be added to the sulfuric acid composition. For example, water or steam can be added to the mixture of sulfuric acid and hydrogen peroxide. Water may be added to the sulfuric acid composition as or after the sulfuric acid composition passes through a dispense nozzle. Additionally, for example, the exposing of the workpiece to the first stripping agent includes dispensing a liquid-phase sulfuric acid composition comprising sulfuric acid and/or its desiccating species and precursors, and exposing the liquid-phase sulfuric acid composition to water vapor in an amount effective to increase the temperature of the liquid-phase sulfuric acid composition above the temperature of the liquid-phase sulfuric acid composition prior to exposure to the water vapor. Furthermore, the substrate may be rotated during the dispensing of the mixed acid stream.

In another embodiment, the one or more process sequences can further include exposing the surface of the workpiece to a second stripping agent containing dilute hydrofluoric acid (dHF). The second stripping agent can include dilute hydrofluoric acid. For example, the dilute hydrofluoric acid can be prepared by diluting concentrated HF solution (e.g., 49 wt % aqueous HF) with water at a dilution ratio of volume parts water to volume parts HF ranging from 50:1 to 1000:1. The dilute hydrofluoric acid can be heated to a temperature ranging from approximately 20 degrees C. to approximately 80 degrees C.

The exposing of the workpiece to a second stripping agent can be performed following the exposing of the workpiece to the first stripping agent. In one example, the exposing of the workpiece to the second stripping agent is performed immediately following the exposing of the workpiece to the first stripping agent. In another example, one or more process steps are inserted between the exposing of the workpiece to the first stripping agent and the exposing of the workpiece to the second stripping agent.

In another embodiment, the one or more process sequences further include exposing the surface of the workpiece to a rinsing agent following the exposing of the workpiece to the first stripping agent and preceding the exposing of the workpiece to the second stripping agent. The rinsing agent can include hydrogen peroxide, deionized (DI) water, hot deionized (HDI), cold deionized (CDI) water, a mixture of HDI and CDI, or a mixture of HDI, CDI, and hydrogen peroxide, or any combinations thereof. HDI can include DI water at a temperature of from about 40 degrees C. to about 99 degrees C. CDI can include DI water at a temperature less than about 40 degrees C., or less than about 25 degrees C., or approximately 20 degrees C.

In yet another embodiment, the one or more process sequences can further include exposing the surface of the workpiece 100 to a cleaning agent. The cleaning agent can contain a mixture of deionized water, aqueous ammonium hydroxide, and hydrogen peroxide to, for example, remove residual sulfuric acid. For example, the cleaning agent can include SC1 composition composed of NH₄OH:H₂O₂:H₂O at a NH₄OH:H₂O₂:H₂O mixture ratio ranging from approximately 1:1:5 to approximately 1:8:500. The mixture ratio expressed above refers to volumetric ratios of approximately 27 wt % to approximately 31 wt % (% by weight) aqueous ammonia solution, approximately 30 wt % to 32 wt % aqueous hydrogen peroxide solution, and water (e.g., the mixture ratio 1:1:5 refers to 1 volume part 27-31 wt % aqueous ammonia solution to 1 volume part 30-32 wt % aqueous hydrogen peroxide solution to 5 volume parts water). The SC1 composition can be adjusted to a temperature in the range of approximately 20 degrees C. to approximately 80 degrees C. Alternatively, or additionally, the cleaning agent can contain a mixture of deionized water, aqueous ammonium hydroxide, and hydrogen chloride to, for example, remove other residue. For example, the cleaning agent can include SC2 composition composed of NH₄OH:HCl:H₂O.

In one example, the exposing of the workpiece to the cleaning agent is performed immediately following the exposing of the workpiece to the first stripping agent, or immediately following the exposing of the workpiece to the second stripping agent. In another example, one or more process steps (e.g. a rinsing step) are inserted between the exposing of the workpiece to the first stripping agent and the exposing of the workpiece to the cleaning agent, or between the exposing of the workpiece to the second stripping agent and the exposing of the workpiece to the cleaning agent.

The inventors have discovered that lower Si content layers can be completely removed by exposing the workpiece to the sulfuric acid composition, i.e., SPM. Lower Si content residual layers can include silicon content less than or equal to 20% by weight, or between 5% and 20% by weight, or between 10% and 20% by weight. The inventors surmise that lower Si content layers can include silicon content less than or equal to 30% by weight, or even less than or equal to 40% by weight. For example, the inventors have observed the complete removal of a silicon containing ARC layer with 17% by weight silicon content by exposing the layer to SPM without subsequent exposure to dHF. The exposure of the workpiece to SPM can be followed by exposure to SC1 to remove residual sulfuric acid. The layer composed of silicon and organic material can be completely removed within a practical time limit, e.g., less than or equal to 300 seconds, or less than or equal to 180 seconds, or less than or equal to 120 seconds, or even less than or equal to 60 seconds.

The inventors have observed that when the silicon content is increased, the complete removal of the layer composed of silicon and organic material can become more challenging. Accordingly, the inventors have discovered that higher Si content layers can be completely removed by exposing the workpiece to the sulfuric acid composition, i.e., SPM, followed by exposing of the workpiece to dilute hydrofluoric acid (dHF). Higher Si content residual layers can include silicon content greater than or equal to 20% by weight, or greater than or equal to 30% by weight, or greater than or equal to 40% by weight. The inventors surmise that the SPM oxidizes the Si containing layer allowing the dHF to attack Si—O bonds, thus causing the eventual removal of the film. For example, the inventors have observed the complete removal of a silicon containing ARC layer with 43% by weight silicon content by exposing the residual layer to SPM, followed by exposure to dHF. The exposure of the workpiece to SPM and dHF can be followed by exposure to SC1 to remove residual sulfuric acid. The layer composed of silicon and organic material can be completely removed within a practical time limit, e.g., less than or equal to 300 seconds, or less than or equal to 180 seconds, or less than or equal to 120 seconds, or even less than or equal to 60 seconds.

The inventors have also observed that exposure of the workpiece to dHF prior to the exposure to SPM does not completely remove the layer composed of silicon and organic material when the silicon content exceeds 40% by weight. And furthermore, the inventors have observed that SPM, followed by APM (ammonium peroxide mixture) does not completely remove the layer when the silicon content exceeds 40% by weight.

By combining all chemistries in a wet clean chamber, i.e., one single wafer wet platform, the multi-layer film stacks can be removed with less cycle time. While the more difficult film to remove in the film stack is the Si containing ARC layer, with Si content ranging from 17% to 43%, the chemistries available in the wet clean chamber can completely remove the Si ARC and multi-layer film stacks.

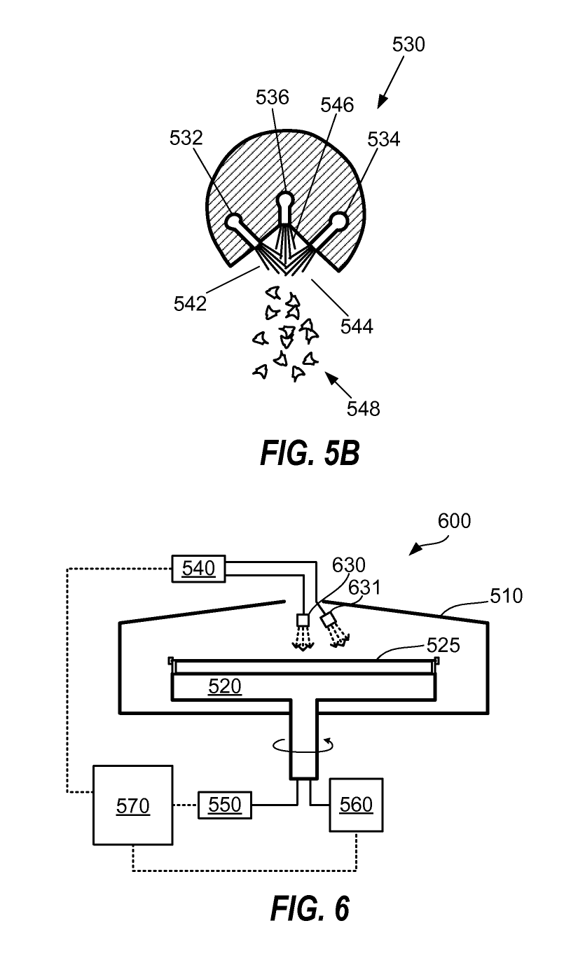

One or more of the methods for stripping material from a workpiece described above may be performed utilizing a wet clean chamber such as the one described in FIG. 5. However, the methods discussed are not to be limited in scope by this exemplary presentation. The method of stripping material from a workpiece according to various embodiments described above may be performed in any one of several systems, including single workpiece systems, batch workpiece systems, dispense or spray-type workpiece systems, workpiece immersion systems, etc.

According to an embodiment, FIG. 5A shows a wet clean system 500 for stripping material from a workpiece 525. While the system is illustrated as a spray-type, single workpiece system; however, other systems are contemplated. The wet clean system 500 includes a wet clean chamber 510 within which workpiece 525 is supported on a rotatable chuck 520 that is driven by a spin motor 560. Spray-type, single workpiece systems have generally been known, including both open and closed systems, and provide an ability to remove liquids with centrifugal force by spinning or rotating the workpiece(s) on a turntable or carousel, either about their own axis or about a common axis.

Spray-type, single and batch workpiece systems are available from TEL FSI, Inc. of Chaska, Minn., e.g., under one or more of the trade designations ORION™, MERCURY™, or ZETA™. Another example of a tool system suitable for adaptation herein is described in U.S. Pat. No. 8,544,483, entitled BARRIER STRUCTURE AND NOZZLE DEVICE FOR USE IN TOOLS USED TO PROCESS MICROELECTRONIC WORKPIECES WITH ONE OR MORE TREATMENT FLUIDS; or U.S. Pat. No. 8,387,635, entitled BARRIER STRUCTURE AND NOZZLE DEVICE FOR USE IN TOOLS USED TO PROCESS MICROELECTRONIC WORKPIECES WITH ONE OR MORE TREATMENT FLUIDS.

The wet clean system 500 can include a first dispense device 530, including a spray bar having a plurality of nozzles to direct liquid onto workpiece 525 in the form of a continuous stream or as liquid aerosol droplets. Additionally, the wet clean system 500 can include a second dispense device 531, including a dispense nozzle to direct liquid onto workpiece 525 in the form of a continuous stream. Alternatively, as shown in FIG. 6, a wet clean system 600 can include a first dispense device 630 and a second dispense device 631, including two or more dispense nozzles to direct liquid onto workpiece 525 in the form of a continuous streams.

As shown in FIG. 5A, a chemical supply system 540 is coupled to the first and second dispense devices 530, 531, and configured to supply, or independently supply, the first and second dispense devices 530, 531 with chemical solution to be dispensed on the workpiece 525. The wet clean system 500 can further include a backside chemical supply system 550 coupled to a back side nozzle (not shown) through rotatable chuck 520, and configured to supply the back side nozzle with chemical solution to be dispensed on the backside of the workpiece 525.

A cross-sectional view of a spray bar, which can be operable as the first dispense device 530 in FIG. 5A, is shown in FIG. 5B, illustrating a preferred nozzle configuration. The spray bar includes an integrally arranged set of orifices in a body that is directed to provide streams that impinge one another. In the configuration as shown, liquid stream orifices 532 and 534 (i.e., acid liquid stream, or sulfuric acid composition) are directed inward to provide impinging liquid streams 542 and 544. Water vapor dispense orifice 536 can be located as shown in this embodiment between liquid stream orifices 532 and 534, so water vapor stream 546 impinges with liquid streams 542 and 544 externally of the nozzle body. As a result of this impingement, atomization can occur, thereby forming liquid aerosol droplets 548.

In addition, the droplets are given enhanced directional momentum toward the surface of the workpiece because of the relatively high pressure of the water vapor stream as it exits from water vapor dispense orifice 536. This centrally located orifice in the nozzle assembly thus provides an advantageous directional aspect to assist in removal of material from the surface of the workpiece. Alternatively, the positioning of the orifices may be reversed, i.e., the liquid stream may be dispensed from orifice 536 and water vapor may be dispensed from orifices 532 and 534.

Optionally, an additional ingredient, such as additional gases and/or vapors, may be dispensed from one or more orifices in the nozzle assembly.

The location, direction of the streams, and relative force of the streams are selected to preferably provide a directional flow of the resulting liquid aerosol droplets, so that the droplets are directed to the surface of a workpiece to effect the desired treatment.

In one embodiment, the liquid aerosol droplets are caused to contact the surface at an angle that is perpendicular to the surface of the workpiece. In another embodiment, the liquid aerosol droplets are caused to contact the surface of the workpiece at an angle of from about 10 to less than 90 degrees from the surface of the workpiece. In another embodiment, the liquid aerosol droplets are caused to contact the surface of the workpiece at an angle of from about 30 to about 60 degrees from the surface of the workpiece. In an embodiment, the workpiece is spinning at a rate of about 10 to about 1000 rpm during contact of the aerosol droplets with the surface of the workpiece. In another embodiment, the workpiece is spinning at a rate of about 50 to about 500 rpm.

The direction of the contact of the droplets with the workpiece may in one embodiment be aligned with concentric circles about the axis of spin of the workpiece, or in another embodiment may be partially or completely oriented away from the axis of rotation of the workpiece. Wet clean system 500 preferably employs suitable control equipment 570 coupled to the chemical supply system 540, the back side chemical supply system, and spin motor 560, among other things, to monitor and/or control one or more of fluid flow, fluid pressure, fluid temperature, combinations of these, and the like to obtain the desired process parameters in carrying out the particular process objectives to be achieved.

Chemical solution, such as sulfuric acid composition, dHF, SC1, DI water, etc., can be provided from liquid supply reservoirs, and be delivered in metered amounts through fluid lines with appropriate control valves, filters, pumps, sensing devices, etc. to dispense devices in the wet clean system 500, 600. Chemistry flow rate, ambient purge gas flow rate, temperature, concentration, rotation/spin rate, etc., are controllable parameters, among others, that can be adjusted in accordance with a selected process recipe and/or target condition.

Using equipment, such as the system depicted in FIG. 5A, the removal of a residual layer composed of silicon and organic material has been demonstrated. In one example, a silicon containing ARC layer with 43% by weight silicon content has been completely removed from a workpiece using a process sequence described above. Table 1 provides three (3) process sequences, labelled “SiARC 1”, “SiARC 2”, and “SiARC 3”. In the first process sequence (“SiARC 1”), the workpiece is exposed to SPM, followed by dHF, followed by SC1.

TABLE 1

| Process | Sequence | Result |
|---|---|---|
| SiARC1 | 30 sec SPM + 60 sec dHF + 60 sec SC1 | Full Strip |
| SiARC2 | 60 sec dHF + 30 sec SPM + 60 sec SC1 | Partial Strip |
| SiARC3 | 30 sec SPM + 60 sec SC1 | Partial Strip |

In preparing the SPM, the sulfuric acid (e.g., sulfuric acid at a concentration of approximately 96 wt % to approximately 98 wt %) is heated to a temperature at or above 180 degrees C. at a first flow rate, then mixed with a hydrogen peroxide solution (e.g., approximately 30 wt % to approximately 32 wt % aqueous hydrogen peroxide) at a second flow rate, and then injected and mixed at point-of-use with steam. In preparing the dHF, concentrated HF solution (e.g., approximately 49 wt % aqueous HF) is diluted with water at 100 volume parts water to 1 volume part concentrated HF solution at room temperature (e.g., 25 degrees C.), and it is dispensed at a third flow rate and atomized using a flow of nitrogen. In preparing the SC1, 1 volume part ammonium hydroxide (e.g., approximately 27 wt % to approximately 31 wt % aqueous ammonia solution) is mixed with 2 volume parts hydrogen peroxide (e.g., approximately 30 wt % to approximately 32 wt % aqueous hydrogen peroxide) and 75 volume parts water at 70 degrees C., atomized using steam, and dispensed on the front side and optionally the back side of the workpiece. While the dispensing of some chemistry may include atomization, the chemistry can be dispensed without atomization, or dispensed with atomization using another material.

As shown in Table 1, the silicon containing ARC layer is fully/completely removed using the first process sequence. However, this film is only partially removed using the second and third process sequence (“SiARC 2”, and “SiARC 3”), wherein the second process sequence alters the order of the SPM and dHF steps, and the third process sequence omits the dHF step.

TABLE 2

| Process | Sequence | Result |
|---|---|---|
| 1 | 30 sec SPM + 20 sec dHF + 20 sec SC1 | Full strip |
| 2 | 30 sec SPM + 20 sec SC1 | Full strip |

In another example, a silicon containing ARC layer with 17% by weight silicon content disposed in a tri-layer film stack (underlying a photoresist layer, and overlying an organic layer) has been completely removed from a workpiece using a process sequence described above. Table 2 provides two (2) process sequences, labelled “1” and “2”.

In preparing the SPM, the sulfuric acid (e.g., sulfuric acid at a concentration of approximately 96 wt % to approximately 98 wt %) is heated to a temperature at or above 180 degrees C. at a first flow rate, then mixed with a hydrogen peroxide solution (e.g., approximately 30 wt % to approximately 32 wt % aqueous hydrogen peroxide) at a second flow rate, and then injected and mixed at point-of-use with steam. In preparing the dHF, concentrated HF solution (e.g., approximately 49 wt % aqueous HF) is diluted with water at 100 volume parts water to 1 volume part concentrated HF solution at room temperature (e.g., 25 degrees C.), and it is dispensed at a third flow rate and atomized using a flow of nitrogen. In preparing the SC1, 1 volume part ammonium hydroxide (e.g., approximately 27 wt % to approximately 31 wt % aqueous ammonia solution) is mixed with 2 volume parts hydrogen peroxide (e.g., approximately 30 wt % to approximately 32 wt % aqueous hydrogen peroxide) and 75 volume parts water at 70 degrees C., atomized using steam, and dispensed on the front side and optionally the back side of the workpiece. While the dispensing of some chemistry may include atomization, the chemistry can be dispensed without atomization, or dispensed with atomization using another material.

The first process sequence exposes the workpiece to SPM, followed by dHF, followed by SC1, and the sequence is successful in completely removing the silicon containing ARC layer. The second process sequence exposes the workpiece to SPM, followed by SC1, excluding dHF, and the sequence is successful in completely removing the silicon containing ARC layer.

Although only certain embodiments of this invention have been described in detail above, those skilled in the art will readily appreciate that many modifications are possible in the embodiments without materially departing from the novel teachings and advantages of this invention. Accordingly, all such modifications are intended to be included within the scope of this invention.

1. A method for stripping material from a microelectronic workpiece, comprising:
receiving a workpiece having a surface exposing a layer composed of silicon and organic material;
placing the workpiece in a wet clean chamber; and
completely removing the layer composed of silicon and organic material from the workpiece by operating the wet clean chamber to perform the following:
exposing the surface of the workpiece to a first stripping agent containing a sulfuric acid composition.

2. The method of claim 1, wherein the layer composed of silicon and organic material has a silicon content less than or equal to 20% by weight.

3. The method of claim 1, wherein the exposing of the workpiece to the first stripping agent includes dispensing a liquid-phase sulfuric acid composition comprising sulfuric acid and/or its desiccating species and precursors, and exposing the liquid-phase sulfuric acid composition to water vapor in an amount effective to increase the temperature of the liquid-phase sulfuric acid composition above the temperature of the liquid-phase sulfuric acid composition prior to exposure to the water vapor.

4. The method of claim 1, wherein the sulfuric acid composition includes sulfuric acid and hydrogen peroxide.

5. The method of claim 4, wherein the sulfuric acid is heated to a temperature ranging from approximately 70 degrees C. to approximately 220 degrees C. prior to mixing the sulfuric acid with hydrogen peroxide.

6. The method of claim 4, wherein the sulfuric acid is heated to a temperature ranging from approximately 170 degrees C. to approximately 200 degrees C. prior to mixing the sulfuric acid with hydrogen peroxide.

7. The method of claim 1, wherein the complete removal of the layer composed of silicon and organic material further comprises:
following the exposing of the workpiece to the first stripping agent, exposing the surface of the workpiece to a second stripping agent containing dilute hydrofluoric acid (dHF).

8. The method of claim 7, wherein the layer composed of silicon and organic material has a silicon content greater than 20% by weight.

9. The method of claim 7, wherein the layer composed of silicon and organic material has a silicon content greater than 30% by weight.

10. The method of claim 7, wherein the layer composed of silicon and organic material has a silicon content in excess of 40% by weight.

11. The method of claim 7, wherein the exposing of the workpiece to the second stripping agent is performed immediately following the exposing of the workpiece to the first stripping agent.

12. The method of claim 7, wherein the complete removal of the layer composed of silicon and organic material further comprises:
exposing the surface of the workpiece to a rinsing agent following the exposing of the workpiece to the first stripping agent and preceding the exposing of the workpiece to the second stripping agent, wherein the rinsing agent is selected from the group consisting of hydrogen peroxide, deionized (DI) water, hot deionized (HDI), cold deionized (CDI) water, a mixture of HDI and CDI, or a mixture of HDI, CDI, and hydrogen peroxide.

13. The method of claim 7, wherein the second stripping agent includes dilute hydrofluoric acid at a dilution ratio of water to HF ranging from 50:1 to 1000:1.

14. The method of claim 13, wherein the dilute hydrofluoric acid is heated to a temperature ranging from approximately 20 degrees C. to approximately 80 degrees C.

15. The method of claim 1, wherein the complete removal of the layer composed of silicon and organic material further comprises:
following the exposing of the workpiece to the first stripping agent, exposing the surface of the workpiece to a cleaning agent containing a mixture of deionized water, aqueous ammonium hydroxide, and hydrogen peroxide to remove residual sulfuric acid.

16. The method of claim 15, wherein the cleaning agent includes SC1 composition composed of NH₄OH:H₂O₂:H₂O at a NH₄OH:H₂O₂:H₂O mixture ratio ranging from approximately 1:1:5 to approximately 1:8:500.

17. The method of claim 16, wherein the SC1 composition is adjusted to a temperature in the range of approximately 20 degrees C. to approximately 80 degrees C.

18. The method of claim 1, wherein the layer composed of silicon and organic material comprises a silicon-containing anti-reflective coating (ARC), and wherein the residual layer has a silicon content approximately equal to 17% by weight, or approximately equal to 43% by weight.

19. The method of claim 1, wherein the layer composed of silicon and organic material is part of a multilayer film stack including remnants of an overlying photo-sensitive material and an optional underlying organic layer.

20. The method of claim 19, further comprising:
exposing the surface of the workpiece to a third stripping agent containing a heated sulfuric acid composition to remove the underlying organic layer.
